(19) United States
(12) Patent Application Publication
(10) Pub. No.: US 2002/0109522 A1
(43) Pub. Date: Aug. 15, 2002

(54) Test system and test method of semiconductor device

(75) Inventors: Heiji Kobayashi, Hyogo (JP); Shinya Nakatani, Hyogo (JP)

Correspondence Address: McDERMOTT, WILL & EMERY, 600 13th Street, N.W., Washington, DC, 20005-3096, US

(73) Assignee: Mitsubishi Denki Kabushiki Kaisha

(21) Appl. No.: 09/935,172

(22) Filed: Aug. 23, 2001

(30) Foreign Application Priority Data
Feb. 9, 2001 (JP) 2001-033379

(51) Int. Cl. G01R 31/26

(52) U.S. Cl. 324/765

(57) ABSTRACT

Using the test result of a tester of a sample test, a table of test conditions is referred to, and the test condition is provided to a tester of a wafer level burn-in test. The product can be ranked to allow testing according to the rank.

### BACKGROUND OF THE INVENTION

1. Field of the Invention

The present invention relates to the testing of a semiconductor memory device such as a DRAM (dynamic random access memory).

2. Description of the Background Art

Following completion of the wafer process, the products are tested according to the flow shown in FIG. 12 to be shipped.

A sample test 100 corresponds to the test of measuring the property of each element forming the device. For example, the transistor property (breakdown voltage Vtd of the gate oxide film of a transistor), line resistance, contact resistance, capacitance Cs of a memory cell capacitor and the like are measured.

The elements subjected to measurement are not the elements incorporated in the device itself. Elements called TEG (test element group) provided as measurement elements at the peripheral region of the device on the wafer are subjected to measurement.

A wafer level burn-in test 200 corresponds to the burn-in test at the wafer level to detect any initial defect at the early stage.

In the burn-in test, failure of the device is accelerated by setting the voltage and ambient temperature more stringent than in actual usage for each device.

A wafer test 300 is directed to classify the products as to good products and bad products.

In wafer test 300, a refresh test that will be described afterwards is applied to obtain the address information of a defective memory cell (defective address) for all the chips on the wafer. The defective address information is analyzed to sort the chips into those that have all the bits operatable using redundant memory cells (repairable) and those not operable (repair impossible).

Trimming 400 is carried out on the repairable chips identified as a result of wafer test 300. Any defective memory cell is replaced with a redundant memory cell by using a replacement circuit provided in the DRAM. As a result, a non-defective chip is obtained.

Assembly 500 is the process of assembling non-defective chips in a package.

Final test 600 is the last test carried out before shipping. Following the packaging step, various tests including the burn-in test are applied.

In the burn-in test, the test condition is set based on the group in which the gate oxide film breakdown voltage Vtd of the transistor is low.

This means that testing is effected under the same condition for devices that can have the burn-in test condition set more stringent to reduce the test time. There was a problem that power consumption is increased and the operation efficiency reduced from the standpoint of the entire testing.

The same applies for the refresh test that will be described afterwards. The test condition is based on a group with low refresh performance. The same refresh time is set for all the non-defective devices.

This means that even a device that has a refresh performance greater than that of the normal device will exhibit refresh performance that does not greatly differ from that of the normal device after the trimming process.

### SUMMARY OF THE INVENTION

In view of the foregoing, an object of the present invention is to provide a test system and test method of a semiconductor memory device that can have the test time reduced and the quality improved.

According to an aspect of the present invention a test system of a semiconductor device, includes a first tester for testing a semiconductor wafer a second tester for testing the semiconductor wafer in a test process implemented after the process of the first tester; and a data processor receiving a test result of the first tester to set one of a plurality of test conditions to the second tester, the data processor having a table storing the plurality of test conditions, and a functional unit referring to the table to select one of the plurality of test conditions to be provided to the second tester, according to the test result of the first tester.

Preferably, the first tester is a tester of a sample test to test a property of an element constituting the semiconductor wafer, and the second tester is a tester of a wafer level burn-in test that carries out a burn-in test at a wafer level.

Particularly, the property includes a breakdown voltage of a gate electrode oxide film of a memory cell transistor formed on the semiconductor wafer.

According to the semiconductor device test system of the present invention, the device can be ranked to allow testing according to the rank.

Particularly, the data processor sets a burn-in voltage and a test time included in the plurality of test conditions of the second tester, according to the breakdown voltage included in the test result of the first tester.

According to the semiconductor device test system of the present invention, the test time and power consumption can be reduced by implementing testing according to the rank of the device.

Preferably, the first tester is a tester of a sample test to test a property of an element constituting the semiconductor wafer, and the second tester is a tester of a final test that implements a burn-in test at a chip level.

Particularly, the property includes a breakdown voltage of a gate electrode oxide film of a memory cell transistor formed on the semiconductor wafer.

According to the semiconductor device test system of the present invention, the device can be ranked to allow testing according to the rank.

Particularly, the data processor sets a burn-in voltage and a test time included in the plurality of test conditions of the second tester, according to the breakdown voltage included in the test result of the first tester.

According to the semiconductor device test system of the present invention, the test time and power consumption can be reduced by implementing testing according to the rank of the device.

Preferably, the first tester is a tester of a sample test testing a property of an element constituting the semiconductor wafer, and

the second tester is a tester of a wafer test that implements a refresh test.

Particularly the property is a plurality of properties of an element including a threshold voltage of a gate electrode of a memory cell transistor and a capacitance of a memory cell capacitor.

Particularly, the data processor sets a pause time included in the plurality of test conditions of the second tester, according to the threshold voltage included in the test results of the first tester.

According to the semiconductor device test system of the present invention, the optimum pause refresh test specification can be determined corresponding to the device performance. The average performance of the device can be improved and stabilization of the yield can be expected.

According to another aspect of the present invention, a test method of a semiconductor device includes a first test step of testing a property of a semiconductor wafer a second test step testing the semiconductor wafer implemented after the first test step; and a data processing step of receiving a test result of the first test step to set one of a plurality of test conditions in the second test step, the data processing step having the steps of referring to a table storing the plurality of test conditions according to the test result of the first test step, and setting one of the plurality of test conditions in the second test step.

Preferably the first test step tests a property of an element constituting the semiconductor wafer, and the second test step implements a burn-in test at a wafer level.

Particularly, the property includes a breakdown voltage of a gate electrode oxide film of a memory cell transistor formed on the semiconductor wafer.

According to the semiconductor device test method of the present invention, the device can be ranked to allow testing according to the rank.

Particularly, the data processing step sets a burn-in voltage and a test time included in the plurality of test conditions of the second test step, according to the breakdown voltage of the gate electrode oxide film of the memory cell transistor that is the test result of the first test step.

According to the semiconductor device test method of the present invention, the test time is reduced to lower power consumption by implementing testing according to the rank of the device.

Preferably, the first test step tests a property of an element constituting the semiconductor wafer, and the second test step implements a burn-in test at a chip level.

Particularly, the first test step tests a property of an element including a breakdown voltage of a gate electrode oxide film of a memory cell transistor.

According to the semiconductor device test method of the present invention, the device can be ranked to allow testing according to the rank.

Particularly, the data processing step sets a burn-in voltage and a test time included in the plurality of test conditions of the second test step, according to the breakdown voltage included in the test result of the first test step.

According to the semiconductor test method of the present invention, the test time is reduced to lower power consumption by implementing testing according to the rank of the device.

Preferably the first test step tests a property of an element constituting the semiconductor wafer, and the second test step implements a refresh test.

Particularly, the property includes a threshold voltage of a gate electrode of a memory cell transistor and a capacitance of a memory cell capacitor, formed on the semiconductor wafer.

Particularly, the data processing step sets a pause time included in the plurality of test conditions of the second tester according to the threshold voltage included in the test results of the first test step.

According to the semiconductor device test method of the present invention, an optimum pause refresh test specification can be determined corresponding to the performance of the device. The average performance of the device can be improved, and stabilization of the yield can be expected.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 represents a test system 1000 according to a first embodiment of the present invention.

FIG. 2 shows an example of a table setting the burn-in test condition.

FIG. 3 represents a test system 2000 according to a second embodiment of the present invention.

FIG. 4 represents the pause refresh characteristics of a device prior to being subjected to trimming 400.

FIG. 5 represents the pause refresh characteristics of a device after being subjected to trimming 400.

FIG. 6 represents the pause refresh characteristics of each device prior to being subjected to trimming 400.

FIG. 7 represents the pause refresh characteristics of each device after being subjected to trimming 400.

FIG. 8 represents the pause refresh characteristics of each device after being subjected to trimming 400.

FIG. 9 shows an example of a table of the pause refresh test specification.

FIG. 10 represents a test system 3000 according to a third embodiment of the present invention.

FIG. 11 is a flow chart of the present invention from completion of a wafer process up to product shipment.

FIG. 12 is a flow chart from completion of a conventional wafer process up to product shipment.

### DESCRIPTION OF THE PREFERRED EMBODIMENTS

Embodiments of the present invention will be described in detail hereinafter with reference to the drawings. In the drawings, the same or corresponding components have the same reference characters allotted, and description thereof will not be repeated.

First Embodiment

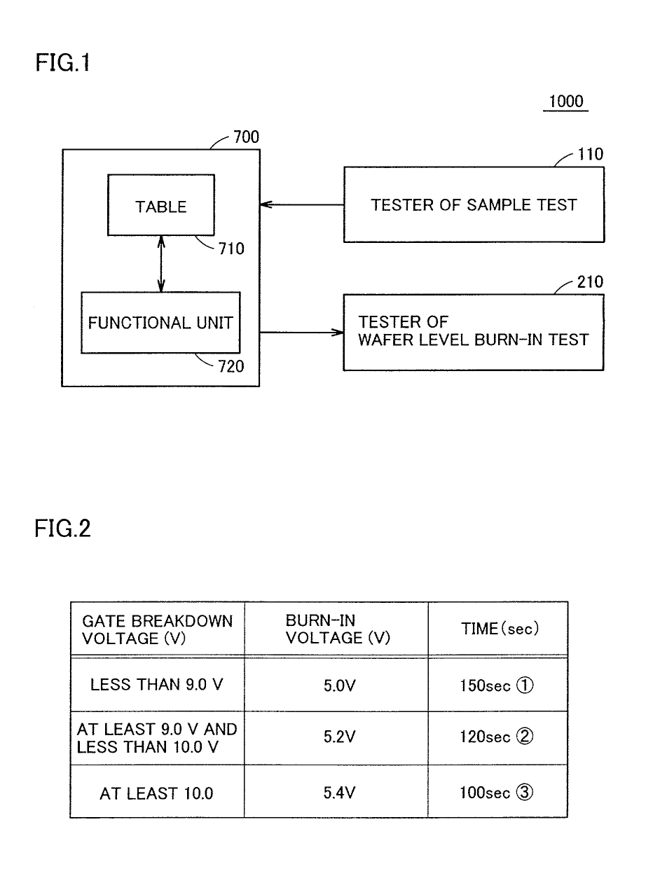

FIG. 1 represents a test system 1000 according to a first embodiment of the present invention.

Test system 1000 includes a tester 110 of a sample test, a tester 210 of a wafer level burn-in test, and a data processor 700.

Sample test tester 110 is a tester to execute sample test 100. The property of each element forming the device is measured. Data of each element is provided to data processor 700.

Data processor 700 includes a table 710 and a functional unit 720.

Functional unit 720 refers to table 710 to rank the device in levels based on the property data of each element applied from sample test tester 110. A test condition corresponding to the ranking is provided to wafer level burn-in test tester 210.

Wafer level burn-in test tester 210 is a tester that carries out wafer level burn-in test 200. Burn-in testing is effected based on the test condition applied from data processor 700.

FIG. 2 shows an example of table 710 in data processor 700.

Conventionally, the burn-in voltage and test time were determined based on the group in which the breakdown voltage Vtd of the gate oxide film of the transistor is low (\mathring{1}).

In the first embodiment, functional unit 720 ranks the device based on the result of breakdown voltage Vtd of the gate oxide film of the transistor, applied from sample test tester 110.

Table 710 is referred to so as to ensure the same quality for each device. As to a device having a high breakdown voltage Vtd of the gate oxide film of the transistor, the burn-in voltage is increased to reduce the test time (\mathring{2}).

As to a device that has a further higher breakdown voltage Vtd of the gate oxide film of the transistor, the burn-in test is additionally increased to further reduce the test time (\mathring{3}).

According to the first embodiment of the present invention, the test time can be reduced by altering the burn-in condition corresponding to the performance of the device.

Second Embodiment

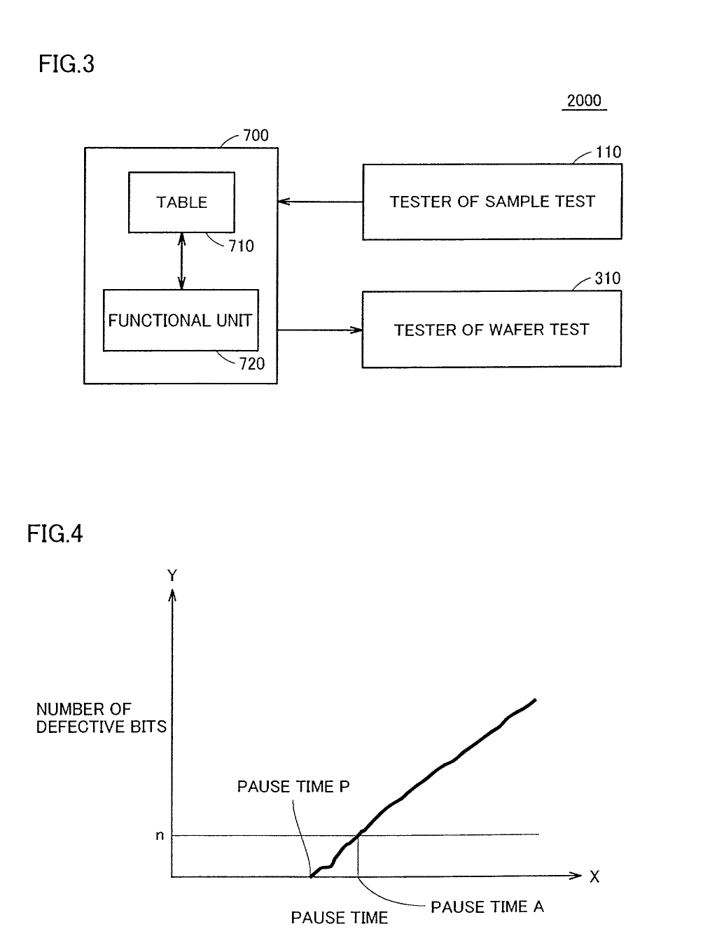

FIG. 3 represents a test system 2000 according to a second embodiment of the present invention.

Test system 2000 includes a tester 110 of a sample test, a data processor 700, and a tester 310 of a wafer test.

Sample test tester 110 provides the property data of each element to data processor 700, as described before.

Data processor 700 includes a table 710 and a functional unit 720.

Data processor 700 ranks the device based on the property data of each element applied from sample test tester 110.

The test condition corresponding to the ranking is provided to wafer test tester 310.

Wafer test tester 310 is a tester that implements a refresh test based on data applied from data processor 700.

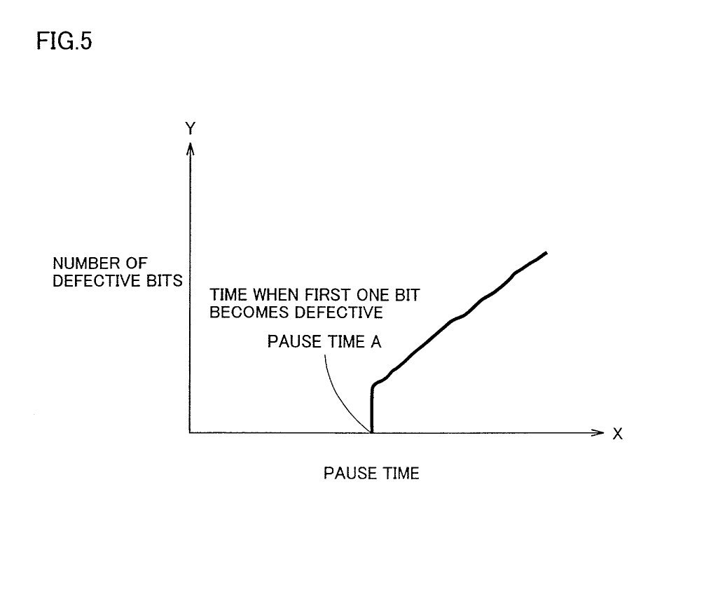

FIG. 4 represents the pause refresh characteristics of a conventional device prior to being subjected to trimming 400 in a refresh test mode.

The X axis corresponds to the pause time, and the Y axis corresponds to the number of defective bits at that pause time (X axis and Y axis are both logarithmic axes, the same applies hereinafter).

Here, Y=n represents the number of bits that can be replaced by trimming.

Pause time P is the time when the first one bit becomes defective. The number of defective bits is n at pause time A.

FIG. 5 represents the refresh characteristics of a conventional device when trimming 400 is implemented in a range where the number of replaceable bits Y does not exceed n in the refresh test.

In FIG. 5, the time A when the first one bit becomes defective corresponds to the refresh time required by this device.

A longer refresh time corresponds to fewer refresh times, which in turn reduces the power consumption for the entire device. Therefore, a long refresh time is to be set.

In a DRAM, the number of redundancy circuits is predetermined for each device. From the number of repairable bits calculated therefrom and the actual performance of the pause refresh characteristics, an appropriate value (pause time A in FIG. 5) is set for the pause refresh test specification.

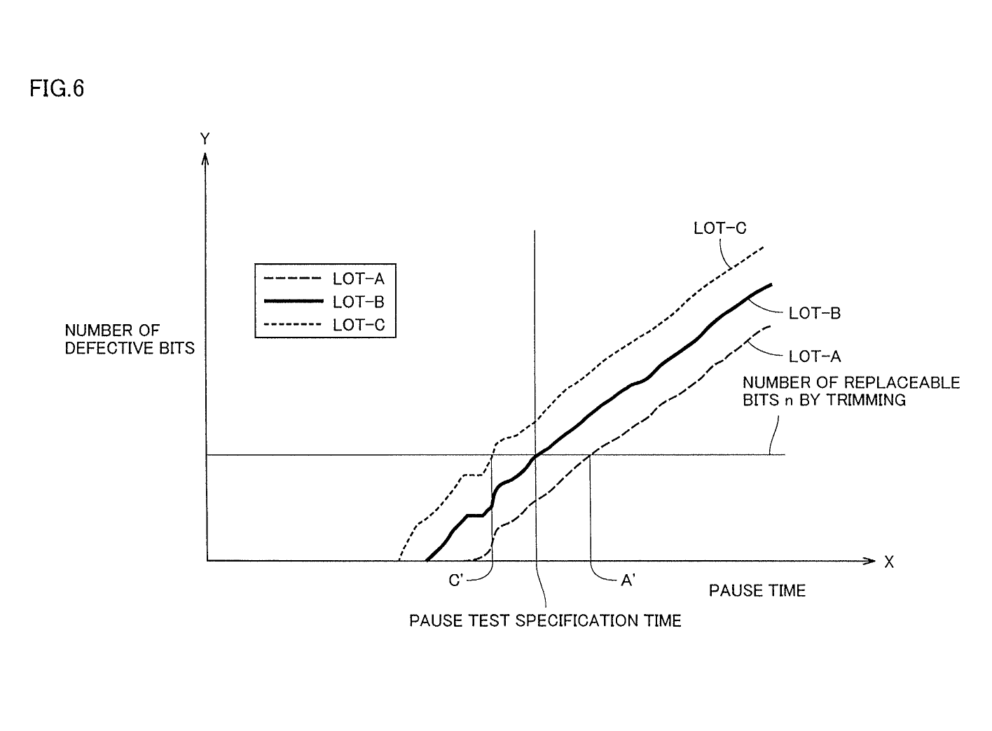

However, devices will vary in practice. As shown in FIG. 6, there are a lot A of favorable pause refresh characteristics, a normal lot B, and a bad lot C.

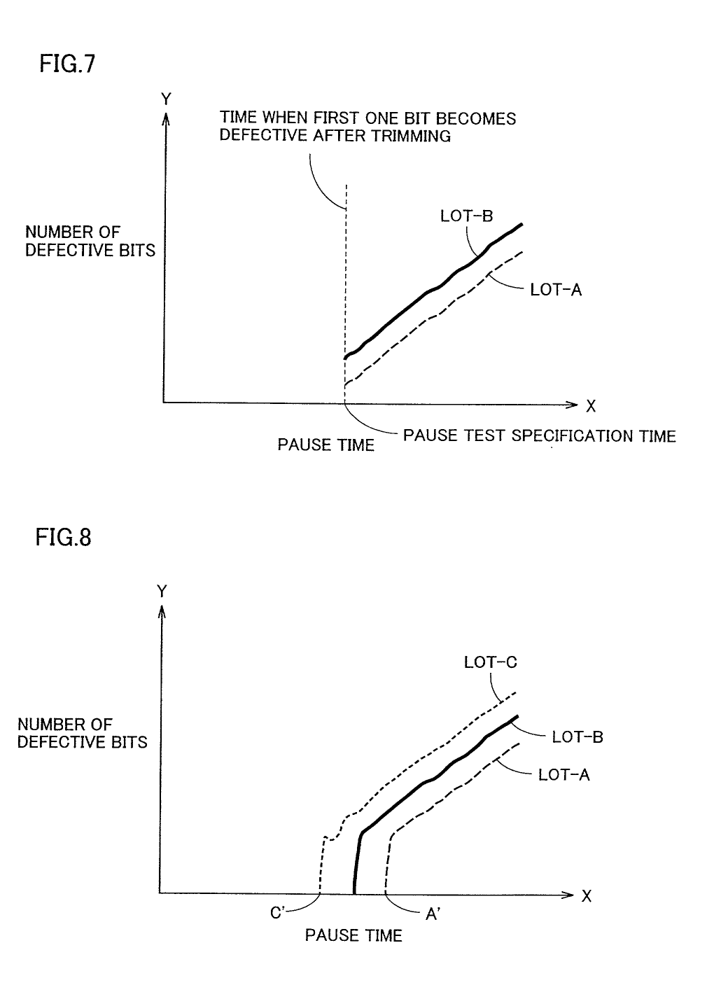

In the conventional method where the pause refresh test specification is fixed, the refresh time is identical for lots A and B subjected to trimming, as shown in FIG. 7. It is to be noted that lot C has a number of defective bits, greater than the number of repairable bits. Therefore, lot C is a faulty product that cannot be repaired.

By determining the pause refresh test specification from the number of repairable bits instead of employing the method where the pause refresh test specification is fixed, the number of defective bits after trimming is as shown in FIG. 8. It is to be noted that the pause time after trimming for lot A of high performance is refresh time A′, which is shorter. Accordingly, the refresh operation is improved than by the conventional method.

Lot C that has low performance can be rendered acceptable by relaxing the pause refresh test specification (set the refresh time to C′).

The number of defective bits must be counted to carry out the above method. This counting consumes a long period of time. For this reason, the capacitance Cs of the memory cell capacitor and the threshold voltage Vth of the memory cell transistor that are dominant factors in determining the property of the number of defective bits are used.

It is to be noted that the refresh characteristic is improved as the capacitance Cs of the memory cell capacitor increases since more charge can be stored.

If the threshold voltage Vth of the memory cell transistor is too high, the current drivability is degraded so that sufficient charge cannot be stored (insufficient writing).

If the threshold voltage Vth is too low, the leakage current will be noticeable even when the transistor is off. The charge stored in the memory cell capacitor will be drawn out to degrade the refresh operation.

The pause refresh test specification is determined based on the aforementioned characteristics.

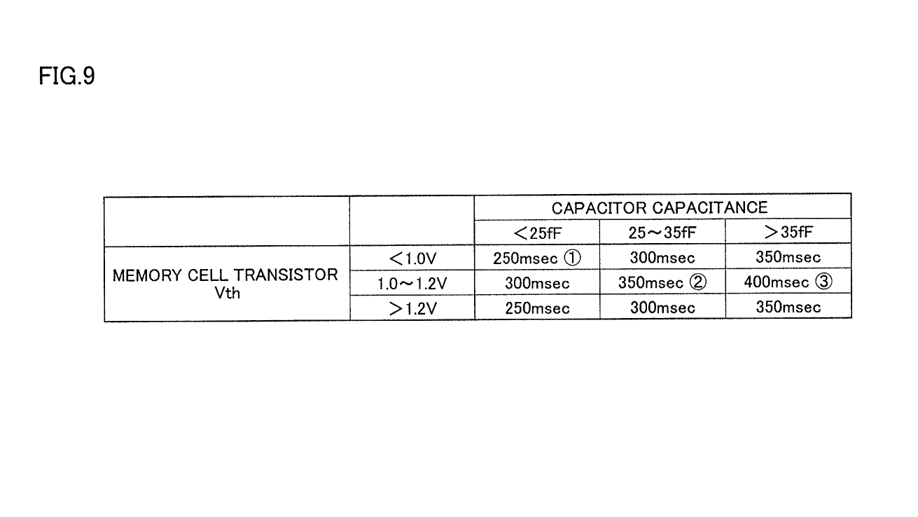

FIG. 9 shows an example of a pause refresh test specification in table 710.

In data processor 700 of the second embodiment of the present invention, functional unit 720 ranks the device based on the results of the capacitance Cs of the memory cell capacitor and threshold voltage Vth of the memory cell transistor, applied from sample test tester 110. An optimum pause refresh test specification of a wafer test is set by referring to table 710.

More specifically, referring to FIG. 9, the period of time of 250 msec (\mathring{1}) is set when the memory cell capacitor has capacitance Cs<25 fF and Vth of the memory cell transistor is Vth<1.0 V for the property of lot A. As to the property of lot B, the time is set to 350 msec (\mathring{2}) when capacitance Cs of the memory cell capacitor is 25 fF to 35 fF and the memory cell transistor Vth is 1.0 V to 1.2 V. As to the property of lot C, the time is set to 350 msec (\mathring{3}) when the memory cell capacitor has Cs>35 fF, and memory cell transistor Vth is 1.0 V to 1.2 V.

By setting the value as described above, the refresh characteristics after trimming 400 is as shown in FIG. 8.

According to the second embodiment of the present invention, devices having high refresh performance can be improved in performance after trimming than a general product. Also, stabilization of the yield can be expected.

Third Embodiment

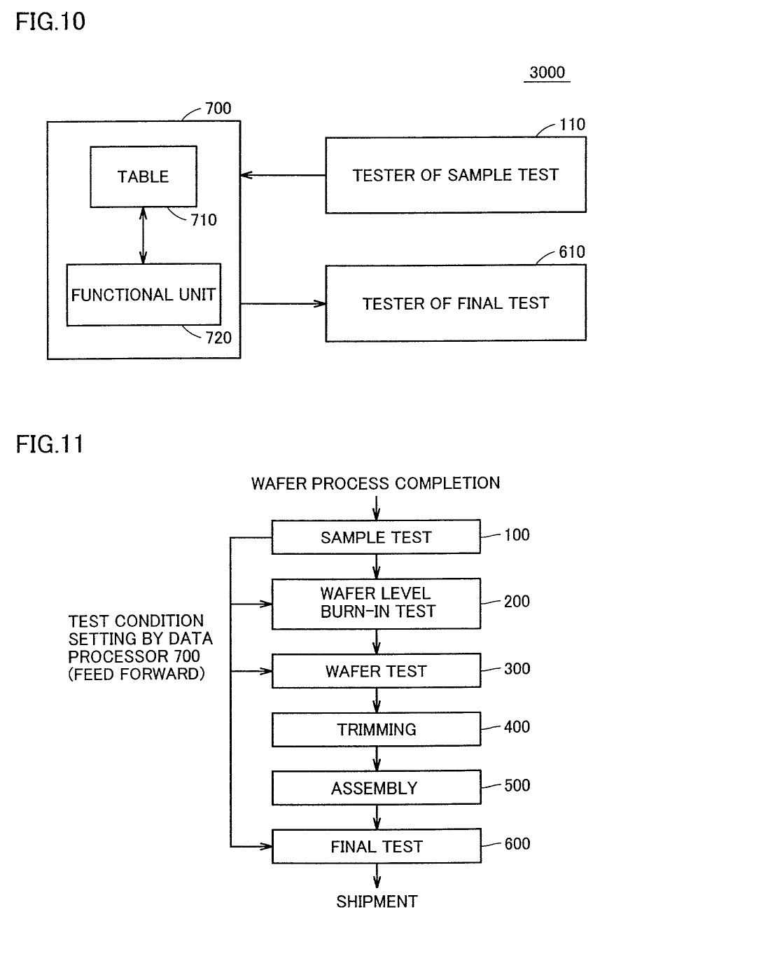

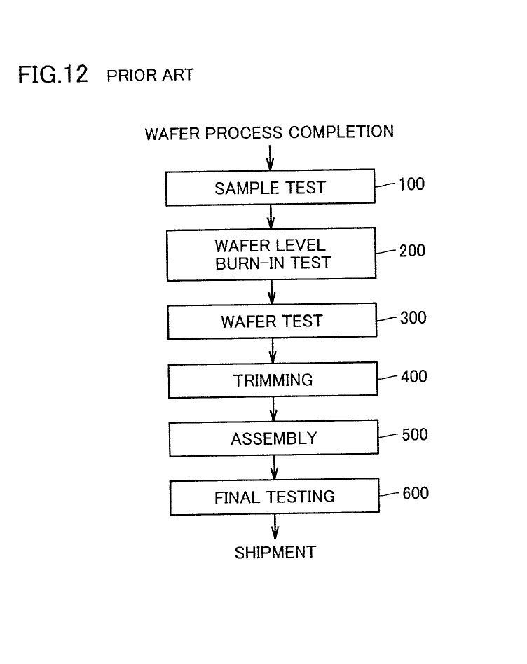

FIG. 10 represents a test system 3000 according to a third embodiment of the present invention.

Test system 3000 includes a tester 110 of a sample test, a tester 610 of a final test, and a data processor 700.

Tester 110 is a tester to execute sample test 100. The property of each element constituting the device is measured. The data of each element is output to data processor 700.

Data processor 700 includes a table 710 and a functional unit 720.

Functional unit 720 refers to table 710 to rank the device in levels based on the property data of each element applied from sample test tester 110. The test condition corresponding to the ranking is provided to final test tester 610.

Tester 610 is a tester to implement various tests including a burn-in test. The test is effected based on data applied from data processor 700.

The method of setting the test condition is as described in the first embodiment.

According to the third embodiment of the present invention, the burn-in test time in the final test can be shortened by altering the burn-in condition corresponding to the device performance.

FIG. 11 is a test flow of the present invention, corresponding to a combination of the aforementioned first to third embodiments.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A test system of a semiconductor device, comprising:
a first tester for testing a semiconductor wafer;
a second tester for testing said semiconductor wafer in a test process implemented after the process of said first tester; and
a data processor receiving a test result of said first tester to set one of a plurality of test conditions to said second tester,
said data processor including
a table storing said plurality of test conditions, and
a functional unit referring to said table to select one of said plurality of test conditions to be provided to said second tester, according to the test result of said first tester.

2. The test system according to claim 1, wherein
said first tester is a tester of a sample test to test a property of an element constituting said semiconductor wafer, and
said second tester is a tester of a wafer level burn-in test that carries out a burn-in test at a wafer level.

3. The test system according to claim 2, wherein
said property includes a breakdown voltage of a gate electrode oxide film of a memory cell transistor formed on said semiconductor wafer.

4. The test system according to claim 3, wherein said data processor sets a burn-in voltage and a test time included in said plurality of test conditions of said second tester, according to said breakdown voltage included in the test result of said first tester.

5. The test system according to claim 1, wherein
said first tester is a tester of a sample test to test a property of an element constituting said semiconductor wafer, and
said second tester is a tester of a final test that implements a burn-in test at a chip level.

6. The test system according to claim 5, wherein said property includes a breakdown voltage of a gate electrode oxide film of a memory cell transistor formed on said semiconductor wafer.

7. The test system according to claim 6, wherein said data processor sets a burn-in voltage and a test time included in said plurality of test conditions of said second tester, according to said breakdown voltage included in the test result of said first tester.

8. The test system according to claim 1, wherein
said first tester is a tester of a sample test testing a property of an element constituting said semiconductor wafer, and
said second tester is a tester of a wafer test that implements a refresh test.

9. The test system according to claim 8, wherein said property is a plurality of properties of an element including a threshold voltage of a gate electrode of a memory cell transistor and a capacitance of a memory cell capacitor.

10. The test system according to claim 9, wherein said data processor sets a pause time included in said plurality of test conditions of said second tester, according to said threshold voltage included in the test results of said first tester.

11. A test method of a semiconductor device comprising:
a first test step of testing a property of a semiconductor wafer;
a second test step testing said semiconductor wafer implemented after said first test step; and
a data processing step of receiving a test result of said first test step to set one of a plurality of test conditions in said second test step,
said data processing step including the steps of referring to a table storing said plurality of test conditions according to the test result of said first test step, and setting one of said plurality of test conditions in said second test step.

12. The test method according to claim 11, wherein
said first test step tests a property of an element constituting said semiconductor wafer, and
said second test step implements a burn-in test at a wafer level.

13. The test method according to claim 12, wherein
said property includes a breakdown voltage of a gate electrode oxide film of a memory cell transistor formed on said semiconductor wafer.

14. The test method according to claim 13, wherein
said data processing step sets a burn-in voltage and a test time included in said plurality of test conditions of said second test step, according to said breakdown voltage of the gate electrode oxide film of the memory cell transistor that is the test result of said first test step.

15. The test method according to claim 11, wherein
said first test step tests a property of an element constituting said semiconductor wafer, and
said second test step implements a burn-in test at a chip level.

16. The test method according to claim 15, wherein
said first test step tests a property of an element including a breakdown voltage of a gate electrode oxide film of a memory cell transistor.

17. The test method according to claim 16, wherein
said data processing step sets a burn-in voltage and a test time included in said plurality of test conditions of said second test step, according to said breakdown voltage included in the test result of said first test step.

18. The test method according to claim 11, wherein
said first test step tests a property of an element constituting said semiconductor wafer, and
said second test step implements a refresh test.

19. The test method according to claim 18, wherein
said property includes a threshold voltage of a gate electrode of a memory cell transistor and a capacitance of a memory cell capacitor, formed on said semiconductor wafer.

20. The test method according to claim 19, wherein said data processing step sets a pause time included in said plurality of test conditions of said second tester according to said threshold voltage included in the test results of said first test step.
